(19) United States
(12) Patent Application Publication
(10) Pub. No.: US 2011/0053373 A1
(43) Pub. Date: Mar. 3, 2011

(54) METHOD FOR MANUFACTURING SEMICONDUCTOR DEVICE

(75) Inventor: Takuya FUTATSUYAMA, Kanagawa-ken (JP)

(73) Assignee: KABUSHIKI KAISHA TOSHIBA, Minato-ku (JP)

(21) Appl. No.: 12/941,791

(22) Filed: Nov. 8, 2010

Related U.S. Application Data
(63) Continuation of application No. 11/842,615, filed on Aug. 21, 2007, now abandoned.

(30) Foreign Application Priority Data
Oct. 3, 2006 (JP) 2006-272186

(51) Int. Cl. H01L 21/768

(52) U.S. Cl. 438/669; 257/E21.575

(57) ABSTRACT

A first insulating film, a second insulating film, a first resist pattern is formed on a semiconductor substrate, the second insulating film is etched to form a second-insulating-film pattern, a third insulating film is deposited over the second-insulating-film pattern to form a third-insulating-film pattern, the first insulating film is etched to form a first-insulating-film pattern, a fourth insulating film and a second resist pattern is formed over the first-insulating-film pattern, fourth insulating film is etched to form a fourth-insulating-film pattern, a fifth insulating film is deposited over the fourth-insulating-film pattern to form a fifth-insulating-film pattern, line parts of first-insulating-film pattern is etched to form a first-insulating-film pattern for wiring, a wiring film is formed over the first-insulating-film pattern for wiring, the wiring film is removed until the first-insulating-film pattern for wiring is exposed to form a wiring pattern.

### CROSS-REFERENCE TO RELATED APPLICATIONS

This application is a continuation of and claims the benefit of priority under 35 U.S.C. §120 from U.S. Ser. No. 11/842,615 filed Aug. 21, 2007, and claims the benefit of priority under 35 U.S.C. §119 from Japanese Patent Application No. 2006-272186 filed Oct. 3, 2006, the entire contents of each of which are incorporated herein by reference.

### FIELD OF THE INVENTION

The present invention relates to methods for manufacturing semiconductor devices, and more particularly to a method for forming wiring patterns such a gate electrode or a wiring metal.

### DESCRIPTION OF THE RELATED ART

Decreasing a size of semiconductor devices is indispensable in order to achieve high integration and high performance. Especially, shrinking of wiring patterns, such as a gate electrode or a wiring metal is important. These wiring patterns are generally formed by lithography, and a minimum feature size of wiring patterns or a pitch of wiring patterns are determined by the resolution of that. However, the resolution of lithography has a limitation resulting from the wavelength of light or an electron beam. Therefore, forming more fine structures than the resolution of lithography by the conventional method is theoretically impossible.

In view of such circumstances, Japanese Patent Application Laid-Open publication No. 2006-156657 discloses the following method. A sidewall pattern composed of a nitride film is formed adjacent to an oxide-film pattern. After removing the oxide-film pattern, an underlying film is etched through the sidewall pattern. Thereby, a wiring pattern having more a fine pattern pitch than the minimum pattern pitch achieved by lithography is formed on a semiconductor substrate.

The method indicated above utilizes the etching process for forming the sidewall pattern. However, controlling of this etching process is usually very difficult. Therefore, a shape of the sidewall pattern and a space width between sidewall patterns vary widely. For this reason, it is difficult to etch the underlying film with a uniform pattern pitch.

### SUMMARY

According to first aspect of the present invention, a method for manufacturing a semiconductor device comprising: (a) forming a first insulating film on a semiconductor substrate; (b) forming a second insulating film on said first insulating film; (c) forming a first resist pattern on said second insulating film, said first resist pattern having a line-and-space pattern with a first space width; (d) etching said second insulating film through said first resist pattern to form a second-insulating-film pattern having the same pattern as said first resist pattern; (e) removing said first resist pattern; (f) depositing a third insulating film over said second-insulating-film pattern on said first insulating film to form a third-insulating-film pattern having a line-and-space pattern with a second space width smaller than said first space width; (g) anisotropically etching said third-insulating-film pattern until said first insulating film is exposed from a bottom of space parts of said third-insulating-film pattern, and anisotropically etching said first insulating film to form a first-insulating-film pattern having a line-and-space pattern with said second space width same as said third-insulating-film pattern; (h) forming a fourth insulating film over said first-insulating-film pattern, space parts of said first-insulating-film pattern being filled with said fourth insulating film; (i) forming a second resist pattern on said fourth insulating film, said second resist pattern having a line-and-space pattern with said first space width and a reverse pattern of said first resist pattern, line parts of said second resist pattern corresponding to space parts of said first-insulating-film pattern and space parts of said second resist pattern corresponding to line parts of said first-insulating-film pattern; (j) etching said fourth insulating film through said second resist pattern until line parts of said first-insulating-film pattern is exposed to form a fourth-insulating-film pattern having the same pattern as said second resist pattern; (k) removing said second resist pattern; (l) depositing a fifth insulating film over said fourth-insulating-film pattern on said first-insulating-film pattern to form a fifth-insulating-film pattern having a line-and-space pattern with said second space width; (m) anisotropically etching said fifth-insulating-film pattern until line parts of said first-insulating-film pattern is exposed from a bottom of space parts of said fifth-insulating-film pattern, anisotropically etching line parts of said first-insulating-film pattern to form a first-insulating-film pattern for wiring having a pattern pitch smaller than that of said first resist pattern and having a line-and-space pattern with second space width; (n) removing said fourth insulating film remaining in space parts of said first-insulating-film pattern for wiring; (o) forming a wiring film over said first-insulating-film pattern for wiring, space parts of said first-insulating-film pattern for wiring being filled with said wiring film; and (p) removing said wiring film until said first-insulating-film pattern for wiring is exposed to form a wiring pattern having a pattern pitch smaller than that of said first resist pattern.

According to second aspect of the present invention, a method of manufacturing a semiconductor device comprising: (a) forming a first insulating film on a semiconductor substrate; (b) forming a wiring film on said first insulating film; (c) forming a second insulating film on said wiring film; (d) forming a first resist pattern on said second insulating film, said first resist pattern having a line-and-space pattern with a first space width; (e) etching said second insulating film through said first resist pattern to form a second-insulating-film pattern having the same pattern as said first resist pattern; (f) removing said first resist pattern; (g) depositing a third insulating film over said second-insulating-film pattern on said wiring film to form a third-insulating-film pattern having a line-and-space pattern with a second space width smaller than said first space width; (h) anisotropically etching said third-insulating-film pattern until said wiring film is exposed from a bottom of space parts of said third-insulating-film pattern, and anisotropically etching said wiring film to form a wiring-film pattern having a line-and-space pattern with said second space width same as said third-insulating-film pattern; (i) forming a fourth insulating film over said wiring-film pattern, space parts of said wiring-film pattern being filled with said fourth insulating film; (j) forming a second resist pattern on said fourth insulating film, said second resist pattern having a line-and-space pattern with said first space width and a reverse pattern of said first resist pattern, line parts of second resist pattern corresponding to space parts of said wiring-film pattern and space parts of second resist pattern corresponding to line parts of said wiring-film pattern; (k) etching said fourth insulating film through said second resist pattern until line parts of said wiring-film pattern is exposed to form a fourth-insulating-film pattern having the same pattern as said second resist pattern; (l) removing said second resist pattern; (m) depositing a fifth insulating film over said fourth-insulating-film pattern on said wiring-film pattern to form a fifth-insulating-film pattern having a line-and-space pattern with said second space width; (n) anisotropically etching said fifth-insulating-film pattern until line parts of said wiring-film pattern is exposed from a bottom of space parts of said fifth-insulating-film pattern, and anisotropically etching line parts of said wiring-film pattern to form a wiring pattern having a pattern pitch smaller than that of said first resist pattern; and (o) removing said fourth insulating film remaining in space parts of said wiring pattern.

### BRIEF DESCRIPTION OF THE DRAWINGS

FIGS. 1(a), 1(b) and 1(c) illustrate cross-sectional views of a semiconductor device for sequentially showing a method for manufacturing a semiconductor device in accordance with a first embodiment of the present invention.

FIGS. 2(a), 2(b) and 2(c) illustrate cross-sectional views of a semiconductor device for sequentially showing a method for manufacturing a semiconductor device in accordance with a first embodiment of the present invention.

FIGS. 3(a), 3(b) and 3(c) illustrate cross-sectional views of a semiconductor device for sequentially showing a method for manufacturing a semiconductor device in accordance with a first embodiment of the present invention.

FIGS. 4(a), 4(b), and 4(c) illustrate cross-sectional views of a semiconductor device for sequentially showing a method for manufacturing a semiconductor device in accordance with a first embodiment of the present invention.

FIGS. 5(a), 5(b) and 5(c) illustrate cross-sectional views of a semiconductor device for sequentially showing a method for manufacturing a semiconductor device in accordance with a second embodiment of the present invention.

FIGS. 6(a), 6(b) and 6(c) illustrate cross-sectional views of a semiconductor device for sequentially showing a method for manufacturing a semiconductor device in accordance with a third embodiment of the present invention.

FIGS. 7(a), 7(b), and 7(c) illustrate cross-sectional views of a semiconductor device for sequentially showing a method for manufacturing a semiconductor device in accordance with a third embodiment of the present invention.

FIG. 8 illustrates a plan view for a layout of a NAND-type EEPROM in accordance with a fourth embodiment of the present invention.

FIG. 9 illustrates a schematic plan view for a cell unit of a NAND-type EEPROM in accordance with a fourth embodiment of the present invention.

FIG. 10 illustrates a plan view for a layout of a photo mask in order to form wiring patterns of a NAND-type EEPROM in accordance with a fourth embodiment of the present invention.

FIG. 11 illustrates a plan view for a layout of a photo mask in order to form wiring patterns of a NAND-type EEPROM in accordance with a fourth embodiment of the present invention.

### DETAILED DESCRIPTION OF THE INVENTION

Hereafter, embodiments of the present invention are explained with reference to drawings.

### First Embodiment

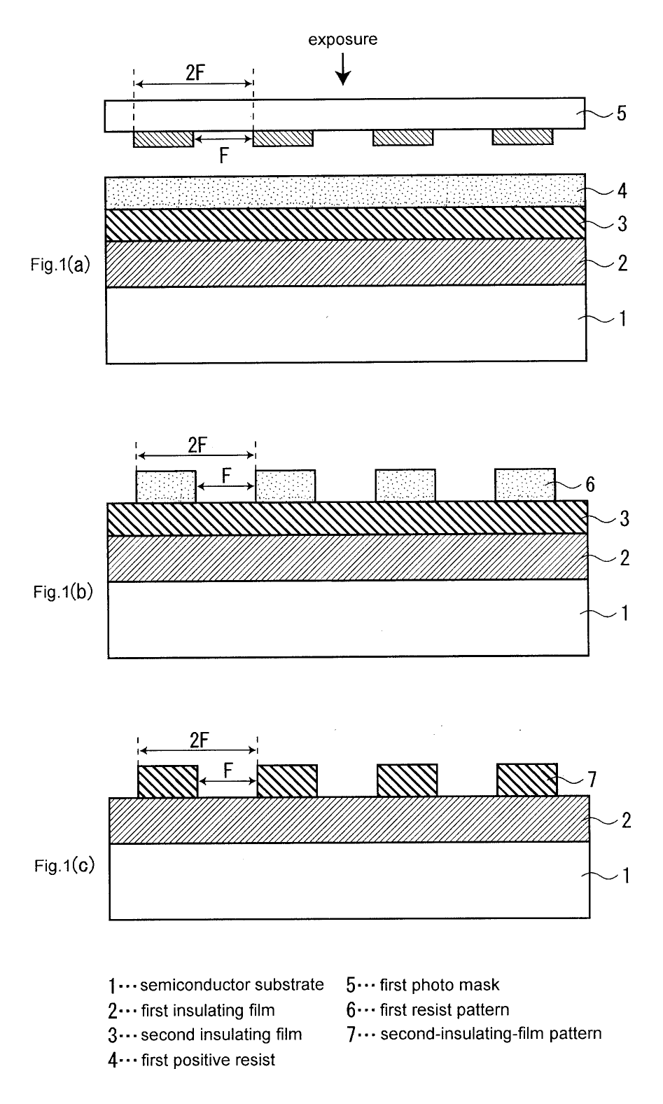

A method for manufacturing a semiconductor device in accordance with a first embodiment of the present invention is explained with reference to FIGS. 1-4. FIGS. 1-4 illustrate cross-sectional views of a semiconductor device for sequentially showing a method for manufacturing a semiconductor device in accordance with the first embodiment of the present invention.

First insulating film 2, such as a silicon nitride film is deposited on semiconductor substrate 1. Second insulating film 3 such as silicon oxide film is deposited on first insulating film 2. In addition, a semiconductor element or a layered material (not shown), such as a transistor, may be formed on semiconductor substrate 1.

First positive resist 4 is coated on second insulating film 3. An exposure process is carried out using first photo mask 5. First photo mask 5 has a line-and-space pattern with the pattern pitch 2F. Both a line part and a space part of this line-and-space pattern have the first space width F (FIG. 1 (a)). The minimum line width or space width (the minimum feature size) achievable by lithography is assumed below F more greatly than F/2.

A development process is carried out to remove first positive resist 4 in the exposed areas. By this development process, first resist pattern 6 is formed on second insulating film 3. First resist pattern 6 has a line-and-space pattern with the pattern pitch 2F. Both a line part and a space part of this line-and-space pattern have the first space width F (FIG. 1 (b)). Second insulating film 3 is etched through first resist pattern 6 to form second-insulating-film pattern 7 on first insulating film 2. Second-insulating-film pattern 7 has the same line-and-space pattern as first resist pattern 6. First resist pattern 6 is removed (FIG. 1 (c)).

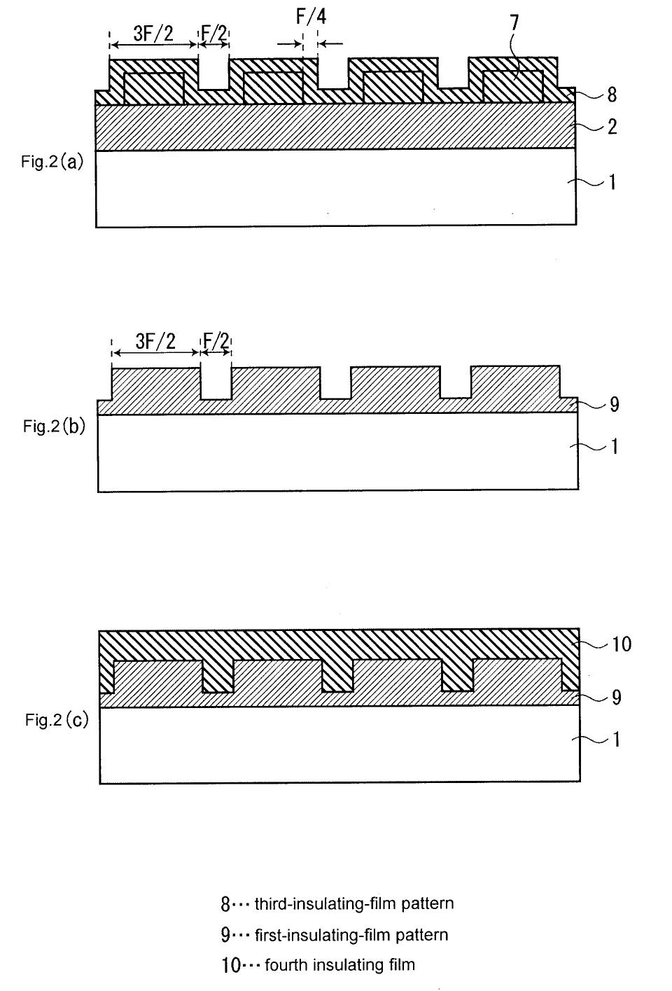

A third insulating film is deposited with the thickness F/4 over second-insulating-film pattern 7 on first insulating film 2 to form third-insulating-film pattern 8. The third insulating film consists of the same material as second insulating film 3, such as a silicon oxide (FIG. 2 (a)). Hereafter, a method for forming a thin film which covers an insulating-film pattern uniformly is called a spacer process. Using the spacer process, third-insulating-film pattern 8 which has a line-and-space pattern with a space part having the second space width F/2 smaller than the first space width F and a line part having the width 3F/2 is formed.

Third-insulating-film pattern 8 is etched by an anisotropic etching process, such as RIE (Reactive Ion Etching). By this etching process, the surface of first insulating film 2 is exposed from a bottom of space parts of third-insulating-film pattern 8. At the same time, the surface of second-insulating-film pattern 7 may be exposed.

This etching process proceeds continuously, thereby first insulating film 2, second-insulating-film pattern 7 and third-insulating-film pattern 8 are etched simultaneously to form first-insulating-film pattern 9. This etching process continues until second-insulating-film pattern 7 and third-insulating-film pattern 8 are all removed. First insulating film 2 is not etched to the surface of semiconductor substrate 1.

However, this etching process may stops when the surface of first insulating film 2 is exposed from a bottom of space parts of third-insulating-film pattern 8. In this case, after changing the etching conditions, another etching process may be applied. By this another etching process, first insulating film 2 may be etched through second-insulating-film pattern 7 and third-insulating-film pattern 8. After etching first insulating film 2, remaining second-insulating-film pattern 7 and third-insulating-film pattern 8 may be removed.

Consequently, First-insulating-film pattern 9 has the same line-and-space pattern as third-insulating-film pattern 8, that is, a space part has the second space width F/2, and a line part has the width 3F/2 (FIG. 2 (b)).

In the conventional case, the sidewall pattern is formed by an etching process. However, controlling this etching process is highly difficult. Therefore, the shape of the sidewall pattern and the space width between sidewall patterns vary widely. For this reason, it is difficult to etch the underlying film with a uniform pattern pitch.

On the other hand, in the first embodiment, a thin film deposition process (spacer process) is used. The thin film deposition process is superior in controlling a film thickness or forming a film with uniform thickness to the etching process. Therefore, third-insulating-film pattern 8 which has a uniform space width is obtained by depositing the third insulating film thinly over second-insulating-film pattern 7. For this reason, it is possible to etch the underlying film, that is, first-insulating-film pattern 9 with a uniform pattern pitch.

Fourth insulating film 10, such as a silicon oxide film is deposited over first-insulating-film pattern 9 at low temperature. Space parts of first-insulating-film pattern 9 are filled with fourth insulating film 10. Fourth insulating film 10 is planarized by a CMP (chemical mechanical polishing) process (FIG. 2 (c)).

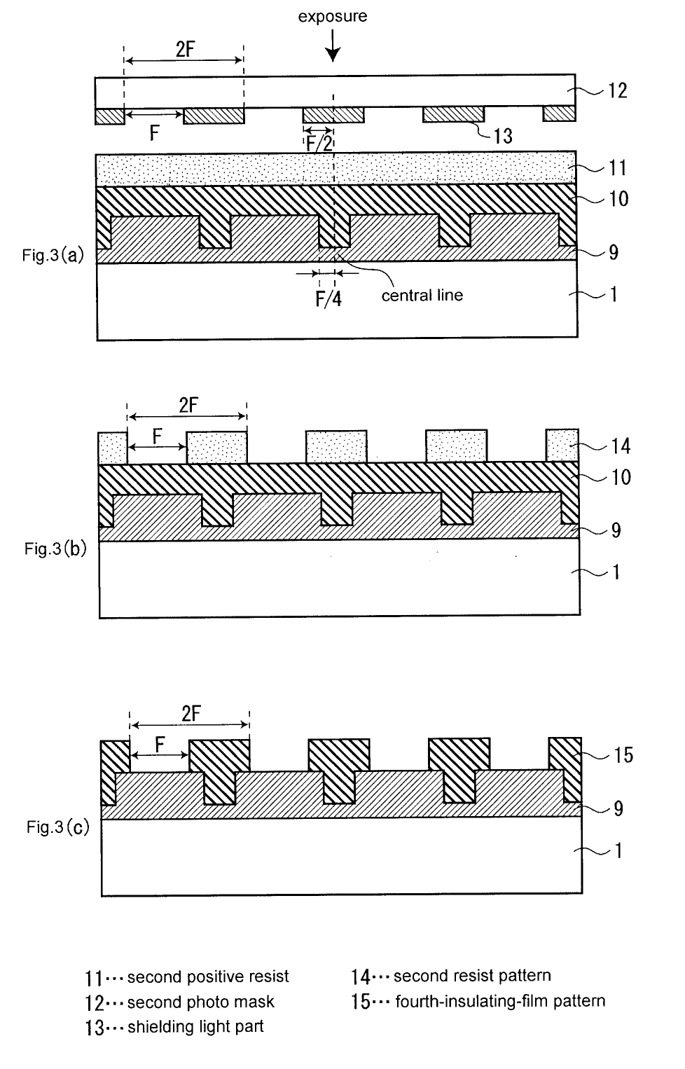

Second positive resist 11 is coated on fourth insulating film 10. An exposure process is carried out using second photo mask 12. Second photo mask 12 has a line-and-space pattern with the pattern pitch 2F and the reverse pattern of first photo mask 5. Both a line part and a space part of this line-and-space pattern have the first space width F. Second photo mask 12 is arranged above second positive resist 11 so that the central line of shielding light part 13 corresponds to the central line of the space part of first-insulating-film pattern 9 (FIG. 3 (a)).

A development process is carried out to remove second resist pattern 14 in the exposed areas. By this development process, second resist pattern 14 is formed on the fourth insulating film 10. Second resist pattern 14 has a line-and-space pattern with the pattern pitch 2F. Both a line part and a space part of this line-and-space pattern have the first space width F (FIG. 3 (b)). Fourth insulating film 10 is etched through second resist pattern 14 to form fourth-insulating-film pattern 15 on first-insulating-film pattern 9. Fourth-insulating-film pattern 15 has the same line-and-space pattern as second resist pattern 14. Line parts of first-insulating-film pattern 9 are exposed from space parts of fourth-insulating-film pattern 15. Second resist pattern 14 is removed (FIG. 3 (c)).

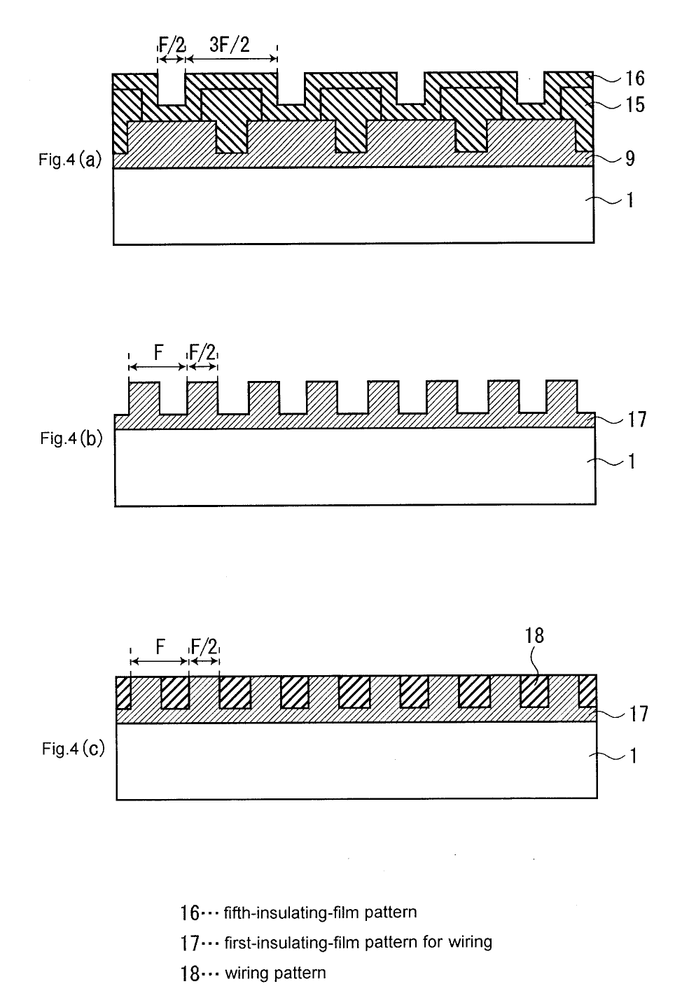

By a spacer process, a fifth insulating film is deposited with the thickness F/4 over fourth-insulating-film pattern 15 on first-insulating-film pattern 9 to form fifth-insulating-film pattern 16. The fifth insulating film consists of the same material as fourth insulating film 10, such as a silicon oxide. Fifth-insulating-film pattern 16 has a line-and-space pattern with a space part having the second space width F/2 and a line part having the width 3F/2 (FIG. 4 (a)).

Fifth-insulating-film pattern 16 is etched by using RIE until the surface of line parts of first-insulating-film pattern 9 is exposed from a bottom of space parts of fifth-insulating-film pattern 16. At the same time, the surface of fourth-insulating-film pattern 15 may be exposed.

This etching process proceeds continuously, thereby first-insulating-film pattern 9, fourth-insulating-film pattern 15 and fifth-insulating-film pattern 16 are etched simultaneously to form first-insulating-film pattern for wiring 17. This etching process continues until the portion of fourth-insulating-film pattern 15 and fifth-insulating-film pattern 16 being out of space parts of first-insulating-film pattern 9 are removed. Line parts of first-insulating-film pattern 9 are etched to the substantially same depth as space parts of first-insulating-film pattern 9. The line part of first-insulating-film pattern 9 is divided into two line parts which have the width F/2. Fourth insulating film 8 which remains in space parts of first-insulating-film pattern for wiring 17 is removed.

However, this etching process may stops when the surface of line parts of first insulating film pattern 9 is exposed from a bottom of space parts of fifth-insulating-film pattern 16. In this case, after changing the etching conditions, another etching process may be applied. By this another etching process, first insulating film pattern 9 may be etched through fourth-insulating-film pattern 15 and fifth-insulating-film pattern 16. After etching first insulating film pattern 9, remaining fourth-insulating-film pattern 15 and fifth-insulating-film pattern 16 may be removed.

Consequently, first-insulating-film pattern for wiring 17 has a line-and-space pattern with the pattern pitch F. This pattern pitch is ½ size of that of first resist pattern 6 and second resist pattern 14. A space part and a line part of first-insulating-film pattern for wiring 17 have the width F/2 (FIG. 4 (b)).

Wiring film, such as Cu film is formed over first-insulating-film pattern for wiring 17. Space parts of first-insulating-film pattern for wiring 17 are filled with wiring film. To form a wiring pattern 18, wiring film is planarized by a CMP process until line parts of first-insulating-film pattern for wiring 17 is exposed. Wiring pattern 18 has a line-and-space pattern with the pattern pitch F. Both a line part and a space part of this line-and-space pattern have the width F/2. That is, the pattern pitch, the width of a line part, and the width of a space part are the ½ size of these of first resist pattern 6 and second resist pattern 14 (FIG. 4 (c)).

In the first embodiment, the thin film deposition process (spacer process) is used. The thin film deposition process is superior in controlling a film thickness or forming a film with uniform thickness to the etching process. Therefore, third-insulating-film pattern 8 and fifth-insulating-film pattern 16 which have the uniform space width F/2 is obtained by depositing the third insulating film and the fifth insulating film with the thickness F/4 over second-insulating-film pattern 7 and fourth-insulating-film pattern 15.

For this reason, first-insulating-film pattern for wiring 17 which has the uniform space width F/2 is formed on semiconductor substrate 1. Consequently, it is possible to obtain wiring pattern 18 which has a line-and-space pattern of the uniform pattern pitch F smaller than the minimum pattern pitch achievable by lithography.

In the explanation of the first embodiment, the pattern pitch of first resist pattern 6 and second resist pattern 14 is 2F, the thickness of third-insulating-film pattern 8 and fifth-insulating-film pattern 16 is F/4, and a line-and-space pattern of the pattern pitch F is formed in the first insulating film 2. However, these conditions may be suitably changed according to the target pattern to be formed in first insulating film 2.

In the explanation of the first embodiment, first insulating film 2 is the silicon nitride film, and second insulating film 3, the third insulating film, fourth insulating film 10 and the fifth insulating film are the silicon oxide film. However, other materials may be used.

Moreover, the depth of spaces formed in first insulating film 2 may be modified by changing the thickness of second insulating film 3, fourth insulating film 10 or etching conditions. For example, it is possible to etch first insulating film 2 until the surface of semiconductor substrate 1 is exposed.

Moreover, in the spacer process, the third insulating film and the fifth insulating film may be suitably thicker rather than the width F/4 in consideration of the etching conversion difference at the time of etching the underlying film.

In the explanation of the first embodiment, the wiring film is Cu film. However, other materials, such as Al film may be used. Moreover, conductive materials other than a metal may be used.

In the explanation of the first embodiment, a positive photo resist is used to form first resist pattern 6 and second resist pattern 14. However, in consideration of the target pattern, a negative photo resist may be used.

### Second Embodiment

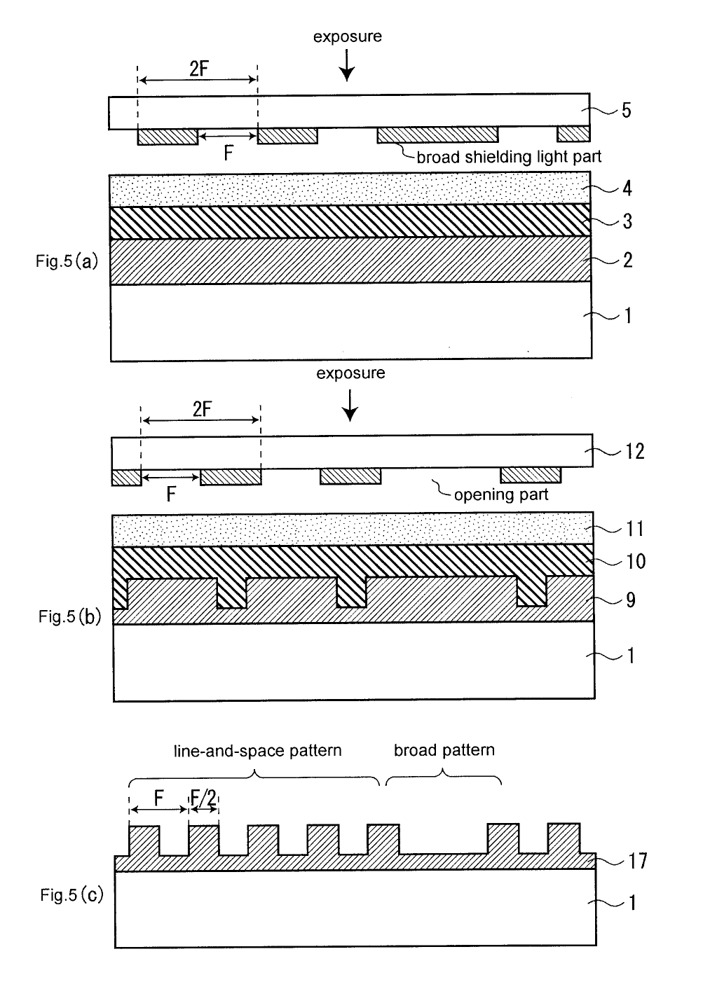

A method for manufacturing a semiconductor device in accordance with a second embodiment of the present invention is explained with reference to FIGS. 5(a), 5(b) and 5(c). FIGS. 5(a), 5(b) and 5(c) illustrate cross-sectional views of a semiconductor device for sequentially showing a method for manufacturing a semiconductor device in accordance with the second embodiment of the present invention.

In the second embodiment, in addition to the method for forming a line-and-space pattern with the pattern pitch F explained in the first embodiment, a method for simultaneously forming a broad pattern with any width adjacent to a line-and-space pattern is explained. The other elements substantially the same in the first embodiment are denoted with the same reference numerals.

First insulating film 2 and second insulating film 3 are laminated on semiconductor substrate 1 same as the first embodiment. First positive resist 4 is coated on second insulating film 3. An exposure process is carried out using first photo mask 5. First photo mask 5 has a line-and-space pattern with the pattern pitch 2F same as the first embodiment, and has a broad shielding light part adjacent to this line-and-space pattern (FIG. 5 (a)).

First insulating film 2 is etched to form first-insulating-film pattern 9 by the same process as the first embodiment. Fourth insulating film 10 and second positive resist 11 is laminated over first-insulating-film pattern 9 (FIG. 5 (b)).

An exposure process is carried out using second photo mask 12. Second photo mask 12 has a line-and-space pattern with the pattern pitch 2F and the reverse pattern of first photo mask 5 same as the first embodiment. Second photo mask 12 has an opening part in the region to be formed a broad pattern.

First-insulating-film pattern 9 is etched to form first-insulating-film pattern for wiring 17 by the same process as the first embodiment. Fourth insulating film 10 which remains in space parts of first-insulating-film-pattern for wiring 17 is removed. Consequently, first insulating film pattern for wiring 17 has a line-and-space pattern with the pattern pitch F smaller than the minimum pattern pitch achievable by lithography, and has a broad pattern with any width adjacent to this line-and-space pattern (FIG. 5 (c)).

As shown in FIG. 4 (c), wiring film is formed over first-insulating-film pattern for wiring 17. Wiring film is planarized by a CMP process until line parts of first-insulating-film pattern for wiring 17 is exposed to form wiring pattern 18. Moreover, the order of steps; the exposure process using first photo mask 5 and the exposure process using second photo mask 12 may be reversed.

### Third Embodiment

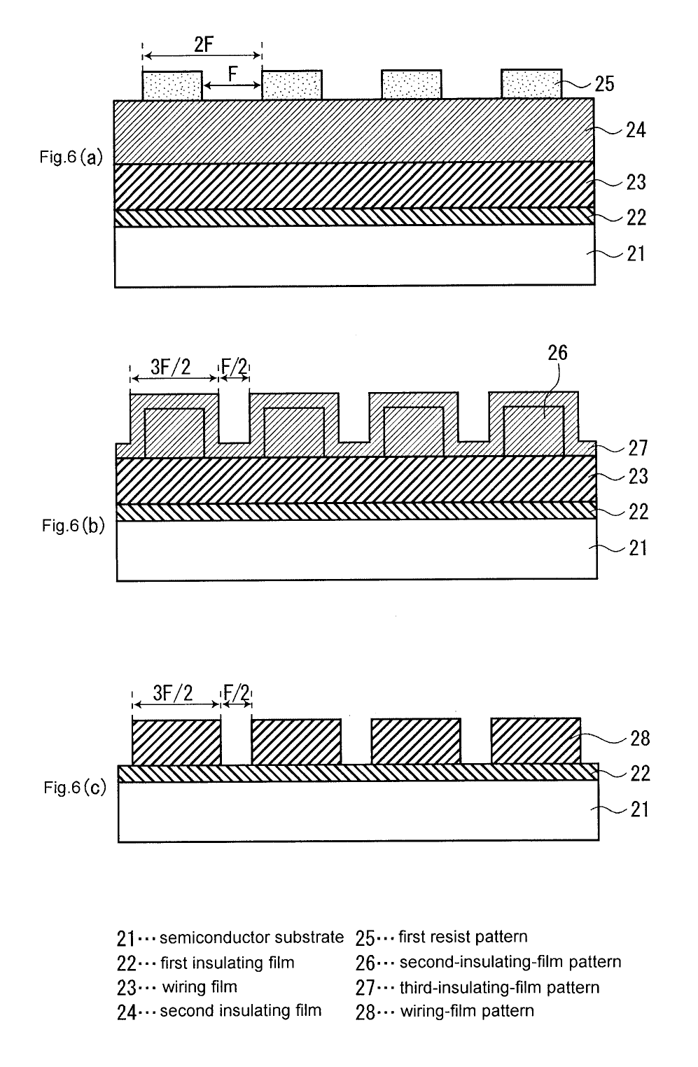

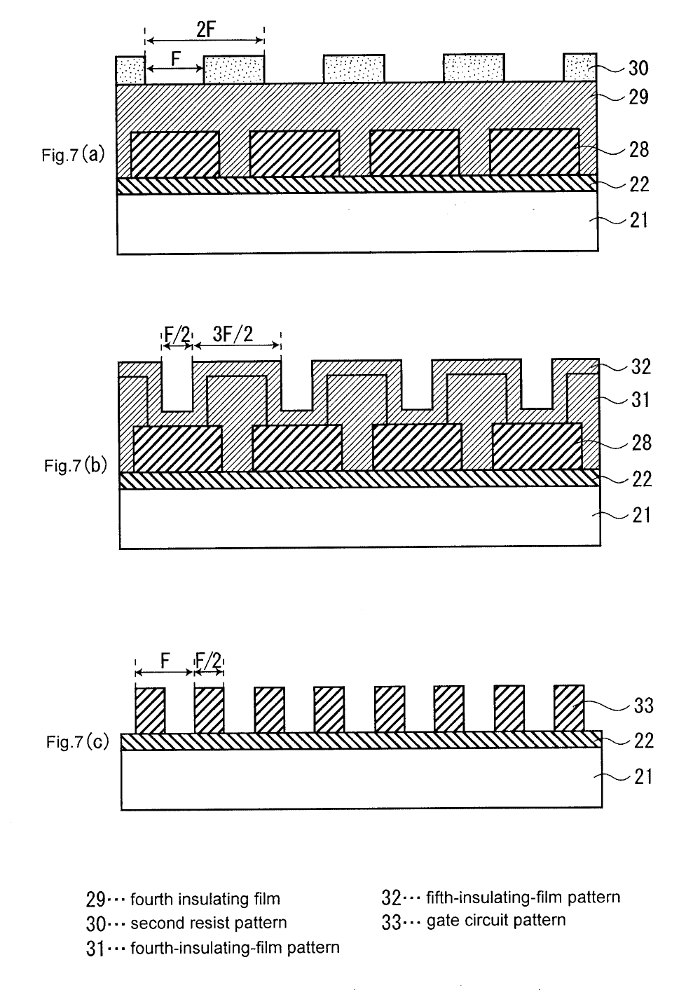

A method for manufacturing a semiconductor device in accordance with a third embodiment of present invention is explained with reference to FIGS. 6 and 7. FIGS. 6 and 7 illustrate cross-sectional views of a semiconductor device for sequentially showing a method for manufacturing a semiconductor device in accordance with the third embodiment of the present invention.

In the third embodiment, same as the method for forming a line-and-space pattern with the pattern pitch F in an underlying film explained in the first embodiment, a method for forming a line-and-space pattern with the pattern pitch F on a semiconductor substrate is explained. The other elements substantially the same in the first embodiment are denoted with the same reference numerals.

First insulating film 22, such as a silicon oxide film is deposited on semiconductor substrate 21. Wiring film 23, such as a poly silicon film is deposited on first insulating film 22. Second insulating film 24, such as a silicon nitride film is deposited on wiring film 23. In addition, a semiconductor element or a layered material (not shown), such as a transistor, may be formed on semiconductor substrate 21.

Positive resist is coated on second insulating film 24. An exposure process is carried out same as the first embodiment to form first resist pattern 25 on second insulating film 24. First resist pattern 25 has a line-and-space pattern with the pattern pitch 2F (FIG. 6 (a)). Both a line part and a space part of this line-and-space pattern have the first space width F. The minimum line width or space width (the minimum feature size) achievable by lithography is assumed below F more greatly than F/2.

Second insulating film 24 is etched through first resist pattern 25 to form second insulating film pattern 26 on wiring film 23. Second insulating film pattern 26 has the same line-and-space pattern as first resist pattern 25. First resist pattern 25 is removed.

A third insulating film is deposited with the thickness F/4 over second-insulating-film pattern 26 on wiring film 23 to form third-insulating-film pattern 27 by a spacer process same as the first embodiment. The third insulating film consists of the same material as second insulating film 24, such as a silicon nitride. Third-insulating-film pattern 27 which has a line-and-space pattern with a space part having the second space width F/2 smaller than the first space width F and a line part having the width 3F/2 is formed (FIG. 6 (b)).

Third-insulating-film pattern 27 is etched by using RIE until the surface of wiring film 23 is exposed from a bottom of space parts of third-insulating-film pattern 27 same as the first embodiment. At the same time, the surface of second-insulating-film pattern 26 may be exposed.

This etching process proceeds continuously, thereby wiring film 23, second-insulating-film pattern 26 and third-insulating-film pattern 27 are etched simultaneously to form wiring-film pattern 28. This etching process continues until second-insulating-film pattern 26 and third-insulating-film pattern 27 are all removed. Wiring film 23 is etched to the surface of first insulating film 22.

However, this etching process may stops when the surface of wiring film 23 is exposed from a bottom of space parts of third-insulating-film pattern 27. In this case, after changing the etching conditions, another etching process may be applied. By this another etching process, wiring film 23 may be etched through second-insulating-film pattern 26 and third-insulating-film pattern 27. After etching wiring film 23, remaining second-insulating-film pattern 26 and third-insulating-film pattern 27 may be removed.

Consequently, wiring-film pattern 28 has the same line-and-space pattern as third-insulating-film pattern 27, that is, a space part has the second space width F/2, and a line part has the width of 3F/2 (FIG. 6 (c)).

Fourth insulating film 29, such as a silicon nitride film is deposited over wiring-film pattern 28 at low temperature. Space parts of wiring-film pattern 28 are filled with fourth insulating film 29. Fourth insulating film 29 is planarized by a CMP process.

A positive resist is coated on fourth insulating film 29. An exposure process is carried out using second photo mask arranged above the positive resist same as the first embodiment. Second resist pattern 30 which has a line-and-space pattern with the pattern pitch 2F is formed on fourth insulating film 29 by a development process. Both a line part and a space part of this line-and-space pattern have the first space width F/2 (FIG. 7 (a)).

Fourth insulating film 29 is etched through second resist pattern 30 to form fourth-insulating-film pattern 31 on wiring-film pattern 28. Fourth-insulating-film pattern 31 has the same line-and-space pattern as second resist pattern 30. Line parts of wiring-film pattern 28 are exposed from space parts of fourth-insulating-film pattern 31. Second resist pattern 30 is removed.

A fifth insulating film is deposited with the thickness F/4 over fourth insulating film 29 on wiring-film pattern 28 to form fifth-insulating-film pattern 32 by a spacer process same as the first embodiment. The fifth insulating film consists of the same material as fourth insulating film 29, such as a silicon nitride. Fifth-insulating-film pattern 32 has a line-and-space pattern with a space part having the second space width F/2, and a line part having the width of 3F/2 (FIG. 7 (b)).

Fifth-insulating-film pattern 32 is etched by using RIE until the surface of line parts of wiring-film pattern 28 is exposed from a bottom of space parts of fifth-insulating-film pattern 32. At the same time, the surface of fourth-insulating-film pattern 31 may be exposed.

This etching process proceeds continuously, thereby wiring-film pattern 28, fourth-insulating-film pattern 31 and fifth-insulating-film pattern 32 are etched simultaneously to form gate circuit pattern 33. This etching process continues until the portion of fourth-insulating-film pattern 31 and fifth-insulating-film pattern 32 being out of space parts of wiring-film pattern 28 are removed. Line parts of wiring-film pattern 28 are etched to the surface of first insulating film 22. The line part of wiring film pattern 28 is divided into two line parts which have the width F/2. Fourth-insulating-film pattern 31 which remains in space parts of gate circuit pattern 33 is removed.

However, this etching process may stops when the surface of line parts of wiring-film pattern 28 is exposed from a bottom of space parts of fifth-insulating-film pattern 32. In this case, after changing the etching condition, another etching process may be applied. By this another etching process, wiring-film pattern 28 may be etched through fourth-insulating-film pattern 31 and fifth-insulating-film pattern 32. After etching wiring-film pattern 28, remaining fourth-insulating-film pattern 31 and fifth-insulating-film pattern 32 may be removed.

Consequently, gate circuit pattern 33 has a line-and-space pattern with the pattern pitch F. Both a line part and a space part of this line-and-space pattern have the width F/2. That is, the pattern, the width of a line part, and the width of a space part are the ½ size of these of first resist pattern 25 and second resist pattern 30 (FIG. 7 (c)).

In the third embodiment, the etching processes for wiring-film pattern 28 shown in FIG. 6 (c) and gate circuit pattern 33 shown in FIG. 7 (c) continue until the surface of first insulating film 22 is exposed. However, these etching processes may continue until the surface of semiconductor substrate 21 is exposed. Or, after forming gate circuit pattern 33 shown in FIG. 7 (c), first insulating film 22 may be etched until the surface of semiconductor substrate 21 is exposed.

In the explanation of the third embodiment, first insulating film 22 is the silicon oxide film, and second insulating film 24, the third insulating film, fourth insulating film 29, and the fifth insulating film are the silicon nitride film. However, other materials may be used.

Furthermore, in the case of forming a nonvolatile memory, the charge storage layer may be formed between first insulating film 22 and wiring film 23. For example, the charge storage layer may be the laminated structure of an insulating films, such as a silicon oxide film—a silicon nitride film—a silicon oxide film. Moreover, the charge storage layer may be the laminated structure of an insulating film and a poly silicon film thereon.

In the explanation of the third embodiment, the pattern pitch of first resist pattern 25 and second resist pattern 30 is 2F, the thickness of third-insulating-film pattern 27 and fifth-insulating-film pattern 32 is F/4, and a line-and-space pattern of the pattern pitch F is formed on first insulating film 22. However, these conditions may be suitably changed according to the target pattern to be formed on first insulating film 22.

In the explanation of the third embodiment, a positive photo resist is used to form first resist pattern 25 and second resist pattern 30. However, in consideration of the target pattern, a negative resist may be used.

### Fourth Embodiment

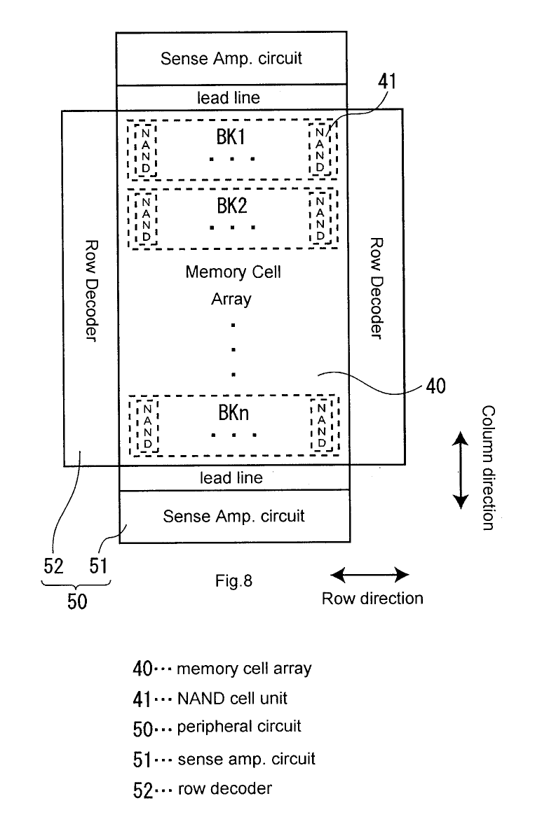

A NAND-type EEPROM in accordance with a fourth embodiment of the present invention is explained with reference to FIGS. 8 to 11. FIG. 8 illustrates a plan view of the NAND-type EEPROM showing the layout of the memory cell array and a peripheral circuit in accordance with the fourth embodiment of present invention.

Memory cell array 40 in NAND-type EEPROM comprises a plurality of blocks BK1, BK2 . . . and BKn as shown in FIG. 8. Furthermore, each block BK1 and BK2 . . . and BKn comprises a plurality of NAND cell unit 41.

Peripheral circuit 50 comprises a control circuit arranged in the direction of a column of memory cell array 40, and a control circuit arranged in the direction of a row of memory cell array 40. In the case of the fourth embodiment, sense amplifier 51 is shown as the control circuit arranged in the direction of a column, and low decoder 52 is shown as the control circuit arranged in the direction of a row.

Sense amplifier 51 is arranged in the direction of a column through lead wirings, and is connected with memory cell array 40 by bit lines. Low decoder 52 is arranged in the direction of a row, and is connected with memory cell array 40 by word lines.

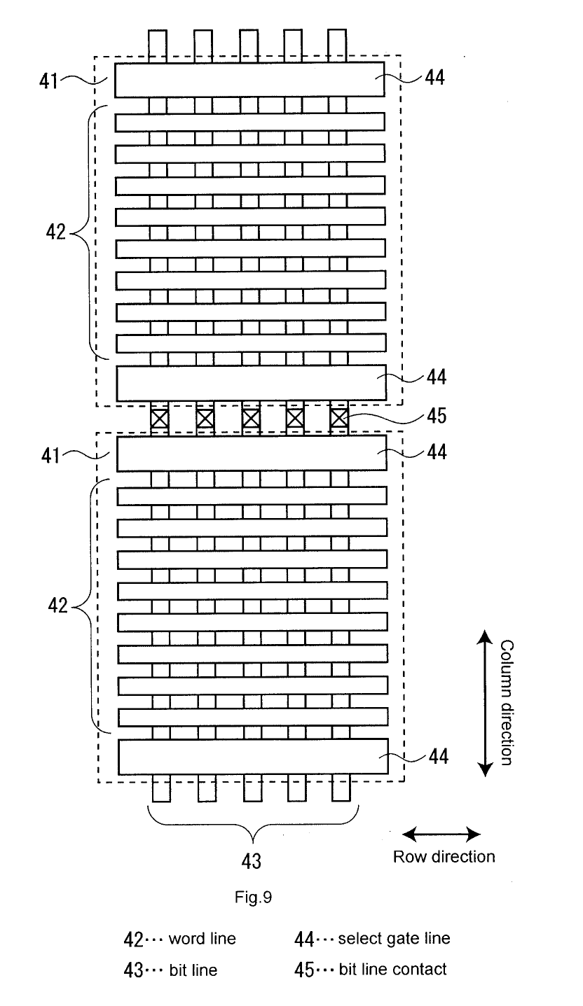

FIG. 9 illustrates a schematic plan view of two NAND cell units 41 which adjacent to each other in the direction of a column as shown FIG. 8. NAND cell unit 41 consists of word line 42, bit line 43, select gate line 44, and bit line contact 45 formed between two select gate line 44.

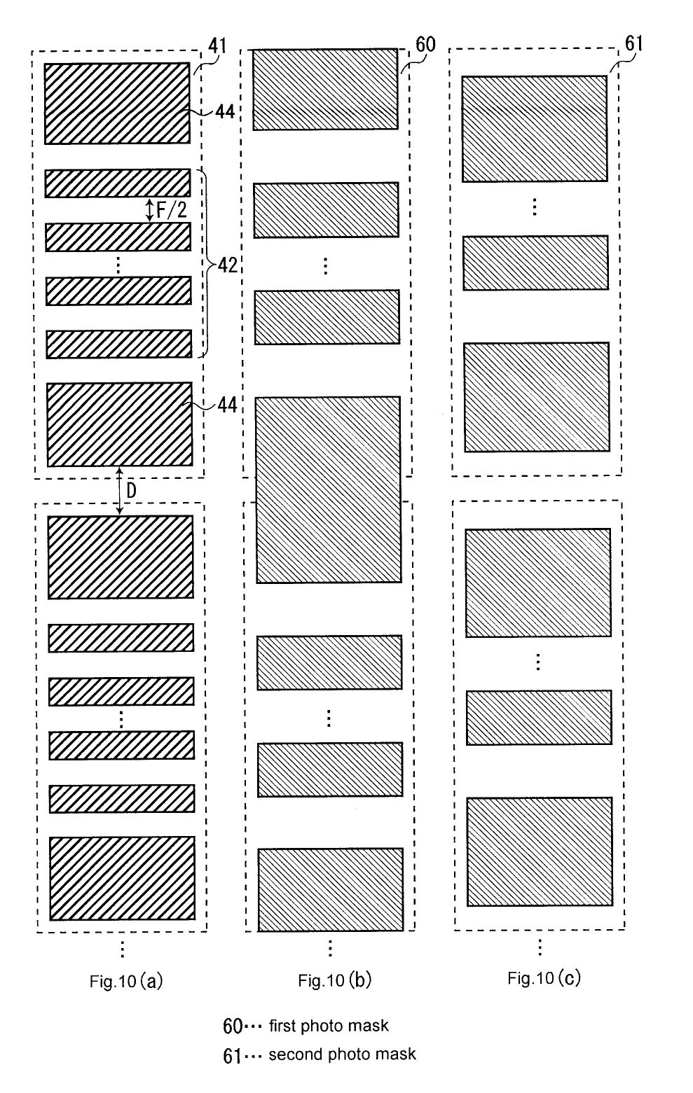

In the fourth embodiment, the method for forming the wiring pattern (word line 42 and select gate line 44) which constitutes NAND cell unit 41 periodically arranged in the direction of a column on a semiconductor substrate is explained with reference to FIG. 10.

FIG. 10 (a) illustrates a plan view of the wiring pattern showing the word line 42 and select gate line 44 which constitutes NAND cell unit 41 periodically arranged in the direction of a column shown in FIG. 9. In the fourth embodiment, word line 42 is periodically formed in the pattern pitch F, and both a line part and a space part of word line 42 have the width F/2. The minimum line width or space width achievable by lithography is below F more greatly than F/2.

Select gate line 44 has any width larger than word line 42, and is formed apart from word line 42 more than the width F/2. In order to simplify the drawing in FIG. 10, word line 42 is omitted in part.

The photo mask for forming the wiring pattern in FIG. 10 (a) is shown in FIGS. 10 (b) and 10(c). FIG. 10 (b) illustrates first photo mask 60, and FIG. 10 (c) illustrates second photo mask 61. The wiring pattern as shown in FIG. 10 (a) is formed by an exposure process using first photo mask 60 and the second photo mask 61. Since the process for forming the wiring pattern is the substantially same as the above-mentioned second embodiment, detailed explanation is omitted.

In the fourth embodiment, the periodical wiring pattern which has a line-and-space pattern (word line 42) with the pattern pitch F smaller than minimum feature size and a broad pattern (select gate line 44) with any width adjacent to word line 42 is formed in NAND cell unit 41. The combination of first photo mask 60 and second photo mask 61 enables two select gate line 44 to be arranged apart from each other with uniform width D, therefore bit line contact 41 is easily formed therebetween.

The order of steps; the exposure process using first photo mask 60 and the exposure process using second photo mask 61 may be reversed.

The present invention may be applied not only for the periodical wiring pattern which comprises word line 42 and select gate line 44 but also for a contact pattern or other wiring layers. Moreover, the present invention may be applied for DRAM (Dynamic Random Access Memory), or other semiconductor memories.

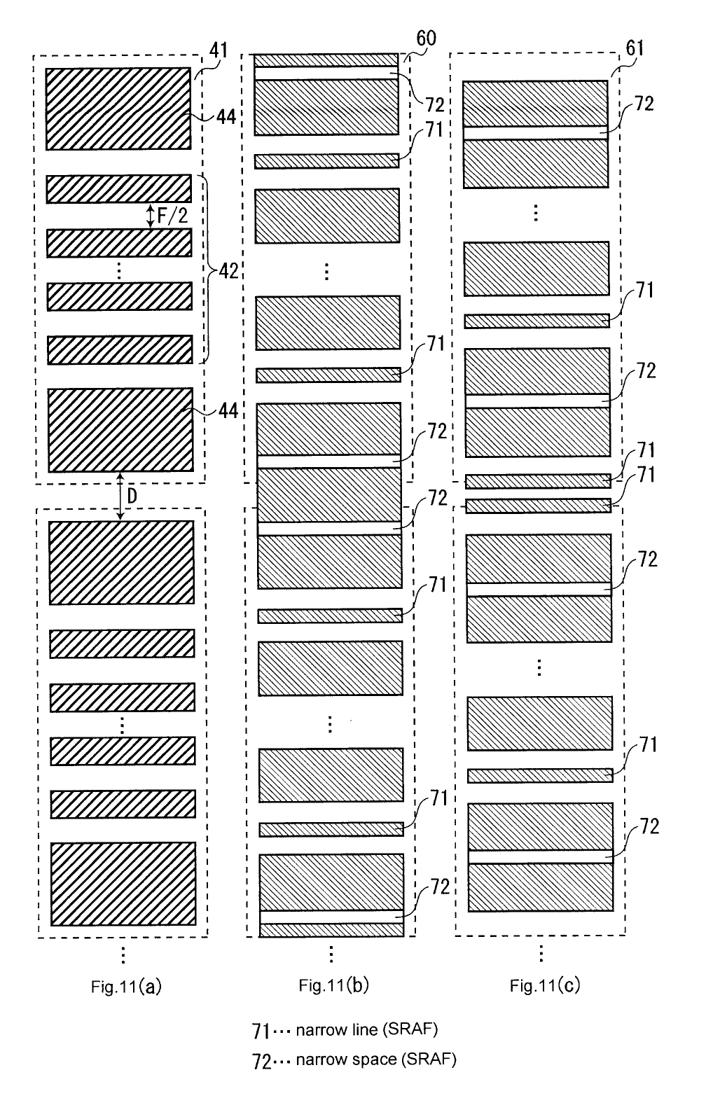

In order to improve the accuracy of above exposure processes, as shown in FIG. 11, assist pattern called SRAF (Sub-Resolution Assist Feature) may be arranged on first photo mask 60 and second photo mask 61. In FIGS. 11 (b) and 11 (c), first photo mask 60 and second photo mask 61 has narrow line 71 which divides broad spaces and narrow space 72 which divides broad lines. Narrow line 71 and narrow space 72 has the width smaller than the resolution limit. By arranging SRAF on first photo mask 60 and second photo mask 61, the accurate target pattern is transferred to a photo resist.

The present invention may be applied for the case of using the reduced lens-optical system which has the reduction ratio such as 4:1 or 5:1.

The present invention is not limited to the above described embodiments but rather can be implemented in various modifications without departing from the concept of the present invention.

What is claimed is:

1. A method for manufacturing a semiconductor device comprising:
(a) forming a first insulating film on a semiconductor substrate;
(b) forming a second insulating film on said first insulating film;
(c) forming a first resist pattern on said second insulating film, said first resist pattern having a line-and-space pattern with a first space width;
(d) etching said second insulating film through said first resist pattern to form a second-insulating-film pattern having the same pattern as said first resist pattern;
(e) removing said first resist pattern;
(f) depositing a third insulating film over said second-insulating-film pattern on said first insulating film to form a third-insulating-film pattern having a line-and-space pattern with a second space width smaller than said first space width;
(g) anisotropically etching said third-insulating-film pattern until said first insulating film is exposed from a bottom of space parts of said third-insulating-film pattern, and anisotropically etching said first insulating film to form a first-insulating-film pattern having a line-and-space pattern with said second space width same as said third-insulating-film pattern;
(h) forming a fourth insulating film over said first-insulating-film pattern, space parts of said first-insulating-film pattern being filled with said fourth insulating film;
(i) forming a second resist pattern on said fourth insulating film, said second resist pattern having a line-and-space pattern with said first space width and a reverse pattern of said first resist pattern, line parts of said second resist pattern corresponding to space parts of said first-insulating-film pattern and space parts of said second resist pattern corresponding to line parts of said first-insulating-film pattern;
(j) etching said fourth insulating film through said second resist pattern until line parts of said first-insulating-film pattern is exposed to form a fourth-insulating-film pattern having the same pattern as said second resist pattern;
(k) removing said second resist pattern;
(l) depositing a fifth insulating film over said fourth-insulating-film pattern on said first-insulating-film pattern to form a fifth-insulating-film pattern having a line-and-space pattern with said second space width;
(m) anisotropically etching said fifth-insulating-film pattern until line parts of said first-insulating-film pattern is exposed from a bottom of space parts of said fifth-insulating-film pattern, and anisotropically etching line parts of said first-insulating-film pattern to form a first-insulating-film pattern for wiring having a pattern pitch smaller than that of said first resist pattern and having a line-and-space pattern with second space width;
(n) removing said fourth insulating film remaining in space parts of said first-insulating-film pattern for wiring;
(o) forming a wiring film over said first-insulating-film pattern for wiring, space parts of said first-insulating-film pattern for wiring being filled with said wiring film; and
(p) removing said wiring film until said first-insulating-film pattern for wiring is exposed to form a wiring pattern having a pattern pitch smaller than that of said first resist pattern.

2. The method for manufacturing a semiconductor device according to claim 1,
wherein said first-insulating-film pattern for wiring has a pattern pitch substantially ½ size of that of said first resist pattern and said second resist pattern.

3. The method for manufacturing a semiconductor device according to claim 2,
wherein said second space width is substantially ½ size of said first space width.

4. The method for manufacturing a semiconductor device according to claim 2,
wherein said third insulating film and said fifth insulating film has substantially ¼ thickness of said first space width.

5. The method for manufacturing a semiconductor device according to claim 2,
wherein said third insulating film consists of the same material as said second insulating film, and said fifth insulating film consists of the same material as said fourth insulating film.

6. The method for manufacturing a semiconductor device according to claim 5,
wherein said second insulating film consists of the same material as said fourth insulating film.

7. The method for manufacturing a semiconductor device according to claim 1,
wherein, in step (g), said first insulating film is not etched to a surface of said semiconductor substrate, and in step (m), said first-insulating-film pattern is not etched to a surface of said semiconductor substrate.

8. The method for manufacturing a semiconductor device according to claim 1,
wherein, in step (g), said second-insulating-film pattern and said third-insulating-film pattern are anisotropically etched until said first insulating film is exposed, and in step (m), said fourth-insulating-film pattern and said fifth-insulating-film pattern are anisotropically etched until said first-insulating-film pattern is exposed.

9. The method for manufacturing a semiconductor device according to claim 1, further comprising, after step (h), before step (i),
(q) polishing said fourth insulating film until a surface of said fourth insulating film being substantially flat.

10. The method for manufacturing a semiconductor device according to claim 1,
wherein, in step (c), said first resist pattern has a first broad pattern adjacent to a line-and-space pattern with said first space width, said first broad pattern having at least one of line and space wider than said first space width, and in step (i), said second resist pattern has a second broad pattern adjacent to a line-and-space pattern with said first space width, said second broad pattern having a reverse pattern of said first broad pattern.

11. A method of manufacturing a semiconductor device comprising:
(a) forming a first insulating film on a semiconductor substrate;
(b) forming a wiring film on said first insulating film;
(c) forming a second insulating film on said wiring film;
(d) forming a first resist pattern on said second insulating film, said first resist pattern having a line-and-space pattern with a first space width;
(e) etching said second insulating film through said first resist pattern to form a second-insulating-film pattern having the same pattern as said first resist pattern;
(f) removing said first resist pattern;
(g) depositing a third insulating film over said second-insulating-film pattern on said wiring film to form a third-insulating-film pattern having a line-and-space pattern with a second space width smaller than said first space width;
(h) anisotropically etching said third-insulating-film pattern until said wiring film is exposed from a bottom of space parts of said third-insulating-film pattern, and anisotropically etching said wiring film to form a wiring-film pattern having a line-and-space pattern with said second space width same as said third-insulating-film pattern;
(i) forming a fourth insulating film over said wiring-film pattern, space parts of said wiring-film pattern being filled with said fourth insulating film;
(j) forming a second resist pattern on said fourth insulating film, said second resist pattern having a line-and-space pattern with said first space width and a reverse pattern of said first resist pattern, line parts of second resist pattern corresponding to space parts of said wiring-film pattern and space parts of second resist pattern corresponding to line parts of said wiring-film pattern;
(k) etching said fourth insulating film through said second resist pattern until line parts of said wiring-film pattern is exposed to form a fourth-insulating-film pattern having the same pattern as said second resist pattern;
(l) removing said second resist pattern;
(m) depositing a fifth insulating film over said fourth-insulating-film pattern on said wiring-film pattern to form a fifth-insulating-film pattern having a line-and-space pattern with said second space width;
(n) anisotropically etching said fifth-insulating-film pattern until line parts of said wiring-film pattern is exposed from a bottom of space parts of said fifth-insulating-film pattern, and anisotropically etching line parts of said wiring-film pattern to form a wiring pattern having a pattern pitch smaller than that of said first resist pattern; and
(o) removing said fourth insulating film remaining in space parts of said wiring pattern.

12. The method for manufacturing a semiconductor device according to claim 11,
wherein said wiring pattern has a pattern pitch substantially ½ size of that of said first resist pattern and said second resist pattern.

13. The method for manufacturing a semiconductor device according to claim 12,
wherein said second space width is substantially ½ size of said first space width.

14. The method for manufacturing a semiconductor device according to claim 12,
wherein said third insulating film and said fifth insulating film has substantially ¼ thickness of said first space width.

15. The method for manufacturing a semiconductor device according to claim 12,
wherein said third insulating film consists of the same material as said second insulating film, and said fifth insulating film consists of the same material as said fourth insulating film.

16. The method for manufacturing a semiconductor device according to claim 15,
wherein said second insulating film consists of the same material as said fourth insulating film.

17. The method for manufacturing a semiconductor device according to claim 11,
wherein, in step (h), said wiring film is etched to a surface of said semiconductor substrate, and in step (n), said wiring-film pattern is etched to a surface of said semiconductor substrate.

18. The method for manufacturing a semiconductor device according to claim 11,
wherein, in step (h), said second-insulating-film pattern and said third-insulating-film pattern are anisotropically etched until said first insulating film is exposed, and in step (n), said fourth-insulating-film pattern and said fifth-insulating-film pattern are anisotropically etched until said wiring-film pattern is exposed.

19. The method for manufacturing a semiconductor device according to claim 11, further comprising, after step (i), before step (j),
(p) polishing said fourth insulating film until a surface of said fourth insulating film being substantially flat.

20. The method for manufacturing a semiconductor device according to claim 11,
wherein, in step (d), said first resist pattern has a first broad pattern adjacent to a line-and-space pattern with said first space width, said first broad pattern having at least one of line and space wider than said first space width, and in step (j), said second resist pattern has a second broad pattern adjacent to a line-and-space pattern with said first space width, said second broad pattern having a reverse pattern of said first broad pattern.
